(19) United States
(12) Patent Application Publication
(10) Pub. No.: US 2009/0161309 A1
(43) Pub. Date: Jun. 25, 2009

(54) Removable hard drive casing

(76) Inventor: Ching Lun Yang, Taipei City (TW)

Correspondence Address: Raymond Sun, 12420 Woodhall Way, Tustin, CA, 92782, US

(21) Appl. No.: 12/004,689

(22) Filed: Dec. 21, 2007

(51) Int. Cl. H05K 5/00; A47B 81/00

(52) U.S. Cl. 361/679.39; 312/223.2

(57) ABSTRACT

A removable hard drive casing for rapidly integrating a hard drive into a computer case, comprising a fixing frame, a hard drive tray and a protective cover. The fixing frame comprises an opening and a receiving space. The hard drive tray can hold the hard drive therein and be inserted and integrated into the receiving space through the opening of the fixing frame. The hard drive tray is provided with a rack on one of the outer sidewalls thereof. The protective cover is a plate-like cover and has two opposite axle ends on the sidewalls thereof, pivotally connected to the opening of the fixing frame. The protective cover further has an arcuate rack corresponding to the rack provided on the outer sidewall of the hard drive tray. The hard drive tray can be moved for a predetermined distance to and from the inside of the fixing frame by means of the arcuate rack on the protective cover driving the rack on the hard drive tray when the protective cover is opened and closed.

### BACKGROUND OF INVENTION

1. Field of the Invention

The present invention relates to a removable hard drive casing, and more particularly, to a removable hard drive casing in which a hard drive tray with a hard drive supported thereon can be pulled out a predetermined distance from a fixing frame when a protective cover is opened, so that the hard drive is simultaneously disengaged from a connection port in a computer case to facilitate retrieving of the hard drive.

2. Description of the Prior Art

FIG. 1 is a schematic sectional view of a conventional removable hard drive casing 1 comprising a base 11, a hard drive tray 12 and a handle 13. The base 11 is fixedly attached to a pre-built drive bay of a computer case. The hard drive tray 12 can hold a hard drive 14 so that the hard drive 14 can be inserted into the base 11 by means of the hard drive tray 12 and then coupled to a connection port 15 at one end of the base 11, so as to be electrically connected to the computer through the connection port 15.

When a user inserts the hard drive tray 12 into the base 11, the force from the user may be applied at different angles and different positions. Therefore, the position of the hard drive tray 12 after being inserted into the base 11 tends to vary, resulting in a positional mismatch of pins and pinholes between the end of the hard drive 14 and the connection port 15 at the end of the base 11, so that the hard drive 14 cannot be successfully coupled to the computer. Furthermore, regardless whether the hard drive tray 12 is being inserted or pulled out, a considerable force is needed to be applied to the handle 13 of the hard drive tray 12 to engage or disengage the hard drive tray 12 from the base 11.

In addition, while the handle 13 on the hard drive tray 12 is usually designed for easy use, the handle 13 itself tends to be projecting from the computer case when the hard drive tray 12 is inserted in the base 11, not only taking space but also giving the computer case an odd look.

### SUMMARY OF INVENTION

Therefore, the first objective of the present invention is to provide a removable hard drive casing wherein a hard drive tray can be pulled out a predetermined distance from within a fixing frame when a protective cover is opened, so that a hard drive supported on the hard drive tray is disengaged from a connection port on a computer case.

The second objective of the present invention is to provide a removable hard drive casing which uses a protective cover to hide the removable hard drive casing itself in a computer case when installed, with the aims of beautification and dust prevention.

The third objective of the present invention is to provide a removable hard drive casing wherein the bottom of a hard drive tray for holding a hard drive thereon is provided with a plurality of apertures, so that heat can be discharged from inside a fixing frame through the apertures and pass through openings of a framework formed at the bottom of the fixing frame.

In order to achieve the aforementioned objectives, a removable hard drive casing for rapidly integrating a hard drive into a computer case is disclosed. The removable hard drive casing comprises a fixing frame, a hard drive tray and a protective cover. The fixing frame comprises an opening and a receiving space. The hard drive tray can hold the hard drive therein and be inserted and integrated into the receiving space through the opening of the fixing frame. The hard drive tray is provided with a rack on one of the outer sidewalls thereof. The protective cover is a plate-like cover and has two opposite axle ends on the sidewalls thereof, pivotally connected to the opening of the fixing frame. The protective cover further has an arcuate rack corresponding to the rack provided on the outer sidewall of the hard drive tray. The hard drive tray can be moved for a predetermined distance to and from the inside of the fixing frame by means of the arcuate rack on the protective cover driving the rack on the hard drive tray when the protective cover is opened and closed.

In a preferred embodiment, the protective cover comprises a resilient fastener on an upper edge thereof for fastening the protective cover to the fixing frame and providing a force-exertion point so that the hard drive tray can be easily pulled out of or pushed into the receiving space of the fixing frame.

In a preferred embodiment, a bottom of the receiving space of the fixing frame is formed with a framework of crisscrossing bars, and the framework has a lead angle at an end thereof where the opening is located, so that the hard drive tray can be easily pushed into the receiving space. The hard drive tray is provided with a plurality of apertures at a bottom thereof, so that heat generated by the hard drive can be discharged through the apertures and pass through openings formed in the framework to go outward the fixing frame.

In a preferred embodiment, the hard drive tray includes a hole at the rear side thereof for electrical connection between the hard drive and a connection port in the computer case.

In a preferred embodiment, the fixing frame includes a plurality of fixing tabs disposed on the outer sidewalls thereof respectively, so that the fixing frame can be attached to the computer case.

In a preferred embodiment, the fixing frame includes a resilient pivot end on each of the two opposite outer sidewalls thereof, so that the axle ends can be attached to the resilient pivot ends.

In a preferred embodiment, the receiving space is provided with a rib on each of two opposite inner sidewalls thereof, so that the hard drive tray can be inserted and integrated into the receiving space through the opening, with a guide rail provided on each of two opposite outer sidewalls of the hard drive tray by moving along undersides of the ribs of the fixing frame.

In a preferred embodiment, the hard drive tray includes a heat dissipation hole on an outer sidewall thereof, so that heat within the hard drive tray can be discharged by a cooling module through the heat dissipation hole. The cooling module can be chosen from one of following: a fan, a thermoelectric cooling module, a heat pipe and a heat sink.

### BRIEF DESCRIPTION OF THE DRAWINGS

The invention as well as a preferred mode of use, further objectives and advantages thereof, will best be understood by reference to the following detailed description of an illustrative embodiment when read in conjunction with the accompanying drawings, wherein:

FIG. 1 is a schematic sectional view of a conventional removable hard drive casing;

FIG. 2 is an exploded view of a removable hard drive casing according to the present invention;

FIG. 3 is a perspective view showing the removable hard drive casing according to the present invention when assembled; and

FIGS. 4A to 4C are schematic views showing the operation of the removable hard drive casing according to the present invention.

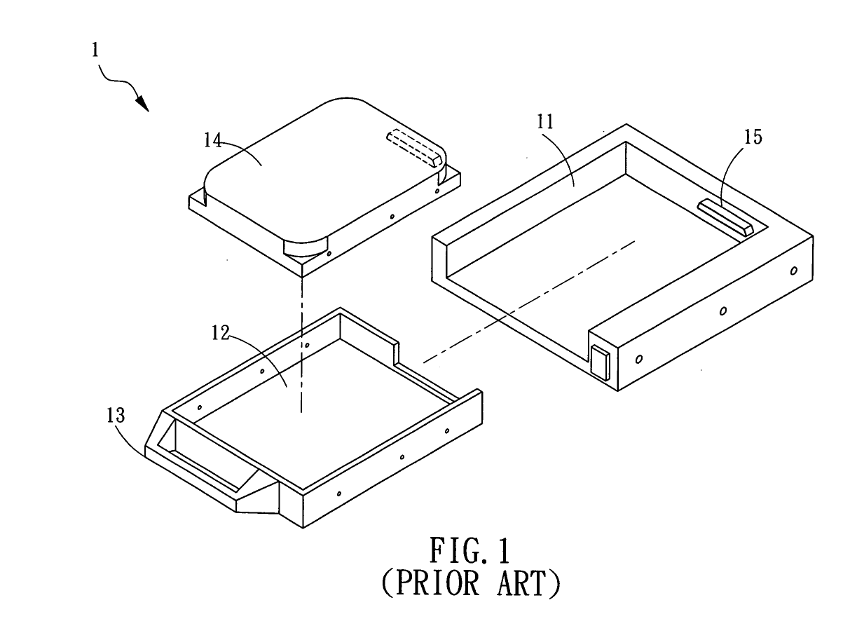

### DETAILED DESCRIPTION

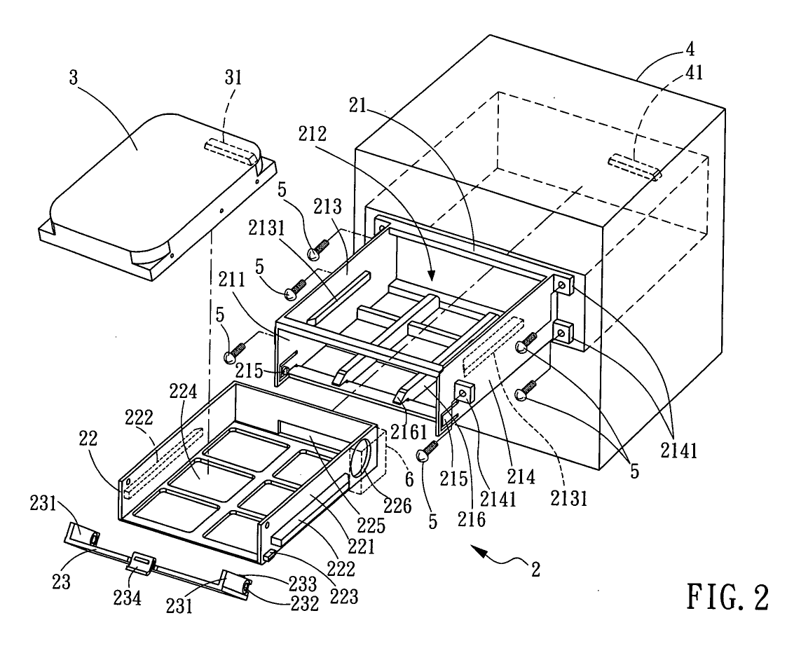

FIG. 2 is an exploded view of a removable hard drive casing according to the present invention. As shown in FIG. 2, a removable hard drive casing 2 is provided for rapidly integrating a hard drive 3 into a computer case 4. The removable hard drive casing 2 comprises a fixing frame 21, a hard drive tray 22 and a protective cover 23.

The fixing frame 21 is a hollow frame with an opening 211 and can be installed in the computer case 4 so that the opening 211 is generally flush with a front surface of the computer case 4. At the center of the fixing frame 21 is an open receiving space 212, whose two opposite inner sidewalls 213 are each provided with a rib 2131. A plurality of fixing tabs 2141 are positioned on each of the two opposite outer sidewalls 214 of the fixing frame 21, so that the fixing frame 21 can be attached to the computer case 4 with a plurality of screws 5. The outer sidewalls 214 on the two sides of the opening 211 are each formed with a resilient pivot end 215, located one opposite the other. The bottom of the receiving space 212 of the fixing frame 21 is constructed as a framework 216 of crisscrossing bars which includes a lead angle 2161 at the end of the framework 216 where the opening 211 is located, so that the hard drive tray 22 can be easily pushed into the receiving space 212 through the opening 211.

The hard drive tray 22 is in the form of a box and serves to hold the hard drive 3. The hard drive tray 22 can move into and fit within the receiving space 212 through the opening 211 by means of guide rails 222 disposed respectively on the two outer sidewalls 221 of the hard drive tray, with the guide rails 222 moving along the undersides of the ribs 2131 inside the fixing frame 21. The hard drive tray 22 further includes a rack 223 on the outer sidewall 221. The bottom side of rack 223 is furnished with a plurality of teeth. The hard drive tray 22 for holding the hard drive 3 is provided with a plurality of apertures 224 at the bottom thereof, so that heat generated by the hard drive 3 can be discharged through the apertures 224 and pass through the openings of the framework 216 formed at the bottom of the fixing frame 21 to the outside of the fixing frame 21.

The hard drive tray 22 includes a hole 225 at the rear side thereof for electrical connection between a connection end 31 of the hard drive 3 and a connection port 41 inside the computer case 4. The hard drive tray 22 further includes a heat dissipation hole 226 on an outer sidewall 221 thereof so that a cooler module 6 can discharge the heat within the hard drive tray 22 through the heat dissipation hole 226. The cooler module 6 can be one of a fan, a thermoelectric cooling module, a heat pipe and a heat sink.

The protective cover 23 is a plate-like cover with a joining section 231 extending perpendicularly therefrom on both sides of the protective cover 23. The joining sections 231 are each formed with an axle end 232 for connecting with the resilient pivot ends 215. An arcuate rack 233 is provided on the outer periphery of the axle end 232 around the same axis as the axle end's in correspondence to the rack 223 on the outer sidewall 221 of the hard drive tray 22. The outer rim of arcuate rack 233 is partially formed with a plurality of teeth which can be meshed with the teeth of the rack 223. The protective cover 23 further includes a resilient fastener 234 attached to an upper edge thereof, so that the protective cover 23 can be fastened to the fixing frame 21 after rotating about the axle ends 232, thereby closing the opening 211. This design not only contributes to an esthetically better look, helps prevent dust, but also provides the user with a force-exertion point so that the hard drive tray 22 can be easily pulled out of or pushed into the receiving space 212 of the fixing frame 21.

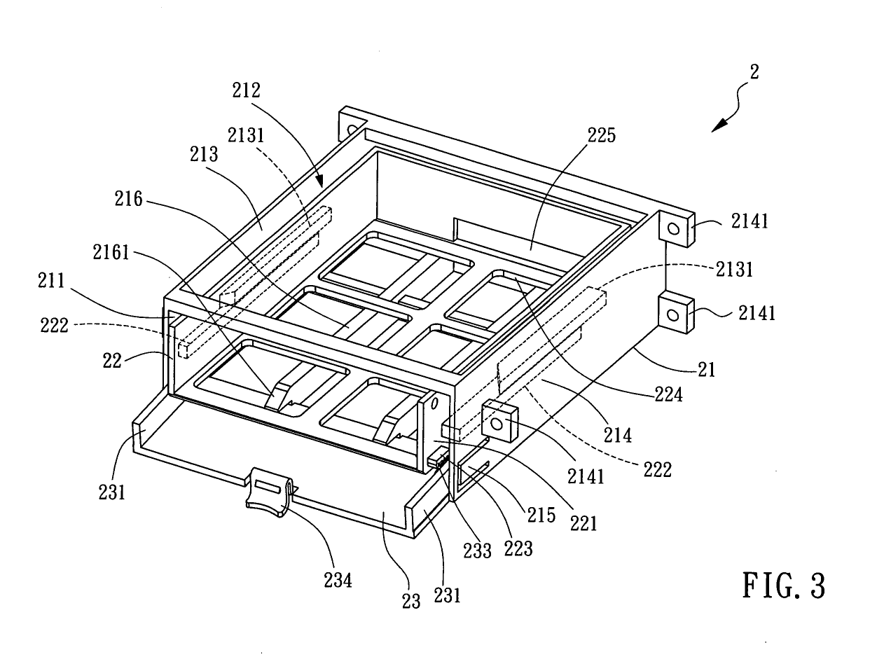

Referring to FIG. 3, which is a perspective view of the removable hard drive casing according to the present invention when assembled. The protective cover 23 has been rotated on the axle ends 232 to open the opening 211, and the hard drive tray 22 is inserted into the receiving space 212 through the opening 211 of the fixing frame 21. The lead angle 2161 provided on the framework 216 facilitates entrance of the hard drive tray 22 into the receiving space 212. The guide rails 222 on the two outer sidewalls 221 of the hard drive tray 22 are retained beneath the ribs 2131, so that the hard drive tray 22 can move inside the receiving space 212 in a stable manner as moving on rails.

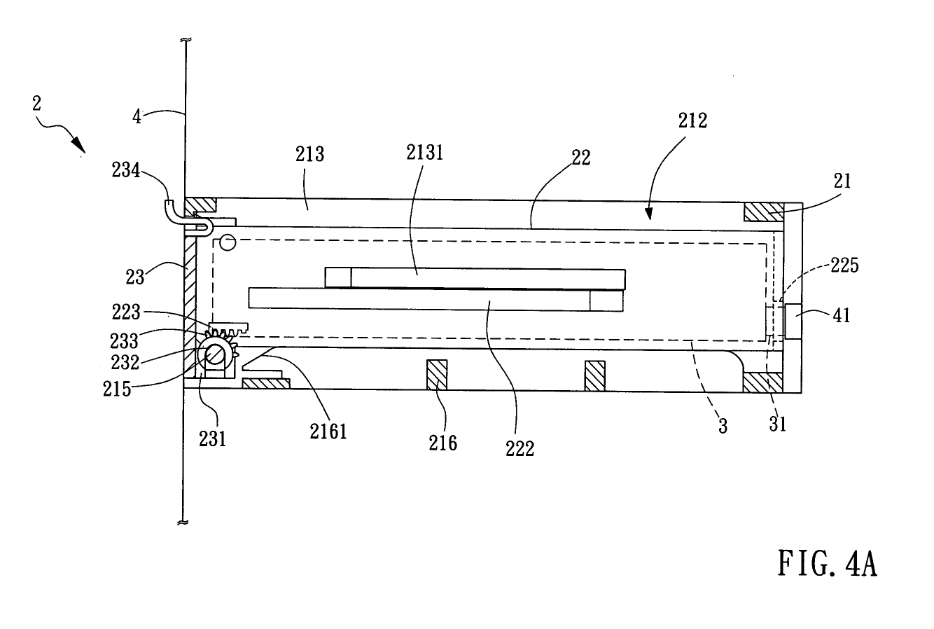

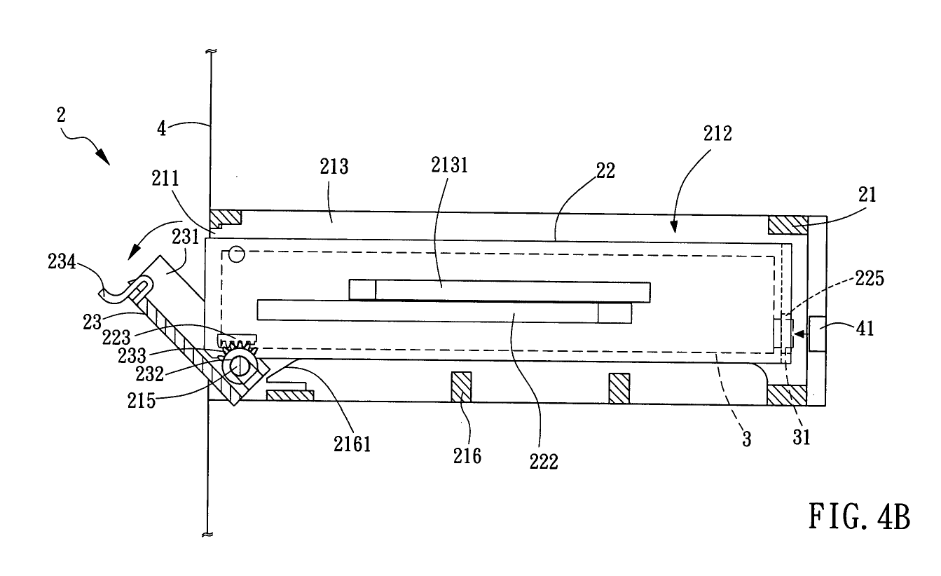

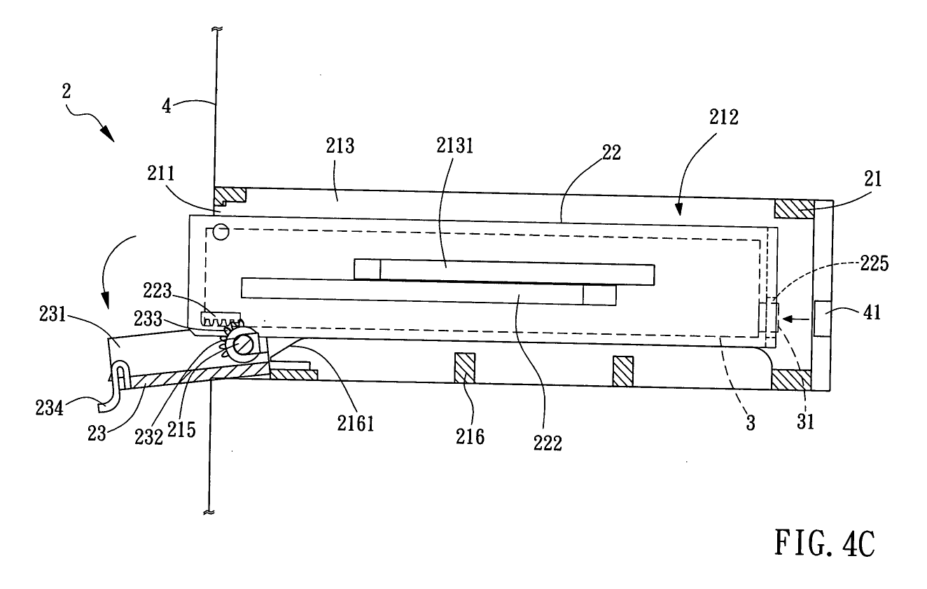

When the hard drive tray 22 is not completely inserted into the receiving space 212, the rack 223 on the outer sidewall 221 of the hard drive tray 22 is meshed with the arcuate rack 233 on the joining sections 231 of the protective cover 23. Now that the axle ends 232 (FIG. 2) are in pivotal connection with he resilient pivot ends 215 of the fixing frame 21 on the same axis, the arcuate rack 233 which is provided on the outer periphery of the axle end 232 around the same axis as the axle ends' can drive the arcuate rack 233 on the hard drive tray 22 when the protective cover 23 is rotated to close the opening 211. By means of the coupled movement of the arcuate rack 233 on the protective cover 23 and the rack 223 on the hard drive tray 22, the hard drive tray 22 is brought another predetermined distance further into the fixing frame 21 while the protective cover 23 is closing. Here so called predetermined distance can be determined either by the length of the teethed rack 223 or by the length of the teethed arcuate rack 233. As shown in FIG. 4, the hard drive tray 22 can be inserted completely in the bottom of the receiving space 212, so that the connection end 31 of the hard drive 3 held in the hard drive tray 22 is electrically coupled to the connection port 41 of the computer case 4 through the hole 225 at the rear end of the hard drive tray 22.

Referring to FIGS. 4A to 4C, which show the operation of the removable hard drive casing according to the present invention. As shown in FIG. 4A, the protective cover 23 is fastened to the fixing frame 21 with the resilient fastener 234, so that the hard drive tray 22 is completely inside the receiving space 212 of the fixing frame 21. The connection end 31 of the hard drive 3 held in the hard drive tray 22 is now in electrical connection with the connection port 41 of the computer case 4 through the hole 225 at the rear end of the hard drive tray 22.

As shown in FIG. 4B, the protective cover 23 is released from the fixing frame 21 by pressing the resilient fastener 234, and rotated outwards on the axle ends 232 about the resilient pivot ends 215 of the fixing frame 21. At the same time, the arcuate rack 233 of the protective cover 23 drives the rack 223 meshed therewith in a counter-clockwise direction, so that the connection end 31 of the hard drive 3 held in the hard drive tray 22 is being disengaged from the connection port 41 of the computer case 4.

As shown in FIG. 4C, the protective cover 23 is completely rotated open. With the arcuate rack 233 of the protective cover 23 driving the rack 223, the hard drive tray 22 has been pulled out a predetermined distance from within the receiving space 212 of the fixing frame 21 in the direction in which the protective cover 23 is opened, so that the hard drive tray 22 generally extends from the opening 211 of the fixing frame 21. The connection end 31 of the hard drive 3 in the hard drive tray 22 is now completely disengaged from the connection port 41 of the computer case 4.

FIGS. 4A to 4C illustrate the process of removing the hard drive tray 2 from the computer case 4, by which process the connection end 31 of the hard drive 3 is simultaneously pulled off of the connection port 41 of the computer case 4, so that the user can draw out the hard drive tray 22 from the receiving space 212 through the opening 211 of the fixing frame 21.

In a reverse order of the process shown in FIGS. 4A to 4C, the hard drive tray 22 can be pushed into the receiving space 212 of the fixing frame 21, so that the rack 223 on the hard drive tray 22 meshes with the arcuate rack 233 on the protective cover 23. When the protective cover 23 is rotated to be fastened to the fixing frame 21, the arcuate rack 233 on the protective cover 23 drives the rack 223 on the hard drive tray 22 meshed therewith in a clockwise direction, so that the hard drive tray 22 is pushed into the receiving space 212, with the guide rails 222 moving along the undersides of the ribs 2131 of the fixing frame 21. The connection end 31 of the hard drive 3 held in the hard drive tray 22 is thereby electrically coupled to the connection port 41 of the computer case 4.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A removable hard drive casing to be installed in a computer case, comprising:
a fixing frame comprising an opening and a receiving space;
a hard drive tray capable of holding a hard drive therein, said hard drive tray being able to be inserted and integrated into the receiving space through the opening, said hard drive tray having a rack on an outer sidewall thereof; and
a protective cover having two opposite axle ends on sides thereof pivotally connected to the opening of the fixing frame, and further having an arcuate rack corresponding to the rack of the hard drive tray;
wherein the hard drive tray can be moved for a predetermined distance inside the receiving space of the fixing frame by means of the arcuate rack on the protective cover driving the rack on the hard drive tray when the protective cover is opened and closed.

2. The removable hard drive casing as claimed in claim 1, wherein said arcuate rack is formed on one of the axle ends; the protective cover further comprises a resilient fastener on an upper edge thereof for fastening the protective cover to the fixing frame and providing a force-exertion point so that the hard drive tray can be easily pulled out of or pushed into the receiving space of the fixing frame.

3. The removable hard drive casing as claimed in claim 1, wherein a bottom of the receiving space of the fixing frame is formed with a framework of crisscrossing bars, and the framework has a lead angle at an end thereof where the opening is located, so that the hard drive tray can be easily pushed into the receiving space.

4. The removable hard drive casing as claimed in claim 3, wherein the hard drive tray is provided with a plurality of apertures at a bottom thereof, so that heat generated by the hard drive can be discharged through the apertures and pass through openings formed in the framework to go outward the fixing frame.

5. The removable hard drive casing as claimed in claim 1, wherein the hard drive tray comprises a hole at the rear side thereof for electrical connection between the hard drive and a connection port in the computer case.

6. The removable hard drive casing as claimed in claim 1, wherein the fixing frame comprises a plurality of fixing tabs disposed on the outer sidewalls thereof respectively, so that the fixing frame can be attached to the computer case.

7. The removable hard drive casing as claimed in claim 1, wherein the fixing frame comprises a resilient pivot end on each of the two opposite outer sidewalls thereof, so that the axle ends can be attached to the resilient pivot ends.

8. The removable hard drive casing as claimed in claim 1, wherein the receiving space is provided with a rib on each of two opposite inner sidewalls thereof, so that the hard drive tray can be inserted and integrated into the receiving space through the opening, with a guide rail provided on each of two opposite outer sidewalls of the hard drive tray by moving along undersides of the ribs of the fixing frame.

9. The removable hard drive casing as claimed in claim 1, wherein the hard drive tray comprises a heat dissipation hole on an outer sidewall thereof, so that heat within the hard drive tray can be discharged by a cooling module through the heat dissipation hole.

10. The removable hard drive casing as claimed in claim 9, wherein the cooling module is chosen from one of following: a fan, a thermoelectric cooling module, a heat pipe and a heat sink.

11. A removable hard drive casing to be installed in a computer case, comprising:
a fixing frame comprising an opening and a receiving space, said fixing frame being able to be fixed inside said computer case;
a hard drive tray capable of holding a hard drive therein, said hard drive tray being able to be inserted and integrated into the receiving space through the opening, said hard drive tray having a rack on an outer sidewall thereof; and
a protective cover pivotally connected to the opening of the fixing frame, and further having an arcuate rack corresponding to and engaged with the rack of the hard drive tray;
wherein, when the protective cover is pivotally turned about the opening, the arcuate rack drives the rack of hard drive tray so as to move the hard drive tray for a predetermined distance.

12. The removable hard drive casing as claimed in claim 11, wherein the protective cover comprises a resilient fastener on an upper edge thereof for fastening the protective cover to the fixing frame and providing a force-exertion point so that the hard drive tray can be easily pulled out of or pushed into the receiving space of the fixing frame.

13. The removable hard drive casing as claimed in claim 11, wherein a bottom of the receiving space of the fixing frame is formed with a framework of crisscrossing bars, and the framework has a lead angle at an end thereof where the opening is located, so that the hard drive tray can be easily pushed into the receiving space.

14. The removable hard drive casing as claimed in claim 13, wherein the hard drive tray is provided with a plurality of apertures at a bottom thereof, so that heat generated by the hard drive can be discharged through the apertures and pass through openings formed in the framework to go outward the fixing frame.

15. The removable hard drive casing as claimed in claim 11, wherein the hard drive tray comprises a hole at the rear side thereof for electrical connection between the hard drive and a connection port in the computer case.

16. The removable hard drive casing as claimed in claim 11, wherein the fixing frame comprises a plurality of fixing tabs disposed on the outer sidewalls thereof respectively, so that the fixing frame can be attached to the computer case.

17. The removable hard drive casing as claimed in claim 11, wherein the protective cover has two opposite axle ends on sides thereof, said arcuate rack is formed on one of the axle ends; the fixing frame further comprises a resilient pivot end on each of the two opposite outer sidewalls thereof, so that the axle ends can be attached to the resilient pivot ends.

18. The removable hard drive casing as claimed in claim 11, wherein the receiving space is provided with a rib on each of two opposite inner sidewalls thereof, so that the hard drive tray can be inserted and integrated into the receiving space through the opening, with a guide rail provided on each of two opposite outer sidewalls of the hard drive tray by moving along undersides of the ribs of the fixing frame.

19. The removable hard drive casing as claimed in claim 11, wherein the hard drive tray comprises a heat dissipation hole on an outer sidewall thereof, so that heat within the hard drive tray can be discharged by a cooling module through the heat dissipation hole.

20. The removable hard drive casing as claimed in claim 19, wherein the cooling module is chosen from one of following: a fan, a thermoelectric cooling module, a heat pipe and a heat sink.
